(19) United States
(12) Patent Application Publication
(10) Pub. No.: US 2026/0342335 A1
(43) Pub. Date: Oct. 29, 2026

(54) SEMICONDUCTOR DEVICE HAVING SCRC SWITCH

(71) Applicant: Micron Technology, Inc., Boise, ID (US)

(72) Inventors: Kumiko Ishii, Sagamihara-shi (JP); Yasuhiko Tanuma, Sagamihara-shi (JP)

(73) Assignee: Micron Technology, Inc., Boise, ID (US)

(21) Appl. No.: 19/646,287

(22) Filed: Apr. 13, 2026

Related U.S. Application Data
(60) Provisional application No. 63/793,421, filed on Apr. 23, 2025.

(51) Int. Cl. H03K 17/687; G11C 11/4074

(52) U.S. Cl. CPC H03K 17/6872; G11C 11/4074

(57) ABSTRACT

Disclosed herein is an apparatus that includes a plurality of first regions in which functional circuits are respectively disposed, and a plurality of second regions in which first SCRC switches each coupled between a first power line supplied with a first power potential and a second power line are respectively disposed. The functional circuit is configured to operate on the first power potential supplied at least from the second power line. The plurality of first regions and the plurality of second regions are arranged in a substantially checkerboarded pattern.

### CROSS-REFERENCE TO RELATED APPLICATIONS

This application claims the filing benefit of U.S. Provisional Application No. 63/793,421, filed Apr. 23, 2025. This application is incorporated by reference herein in its entirety and for all purposes.

### BACKGROUND

There is a case where a semiconductor device such as a DRAM includes pseudo power lines in addition to normal power lines connected to a power pad or an internal power supply circuit. A switch referred to as an SCRC (Sub-threshold Current Reduction Circuit) is connected between a normal power line and a pseudo power line. In a power down state, by turning the SCRC switch off, the leakage current in a circuit connected to the pseudo power line can be reduced.

### BRIEF DESCRIPTION OF THE DRAWINGS

FIG. 1 is a block diagram showing a configuration of a semiconductor device according to an embodiment of the present disclosure;

FIG. 2 is a circuit diagram for explaining a coupling relation between a peripheral circuit and an SCRC switch;

FIGS. 3 and 5 are schematic plan views showing a layout of the peripheral circuit and the SCRC switch;

FIG. 4 is a schematic diagram showing an example of a layout of gate circuits; and

FIGS. 6A and 6B are schematic plan views showing a layout of a peripheral circuit and an SCRC switch according to a modification.

### DETAILED DESCRIPTION

Various embodiments of the present invention will be explained below in detail with reference to the accompanying drawings. The following detailed description refers to the accompanying drawings that show, by way of illustration, specific aspects, and embodiments in which the present invention may be practiced. These embodiments are described in sufficient detail to enable those skilled in the art to practice the present invention. Other embodiments may be utilized, and structural, logical, and electrical changes may be made without departing from the scope of the present invention. The various embodiments disclosed herein are not necessarily mutually exclusive, as some disclosed embodiments can be combined with one or more other disclosed embodiments to form new embodiments.

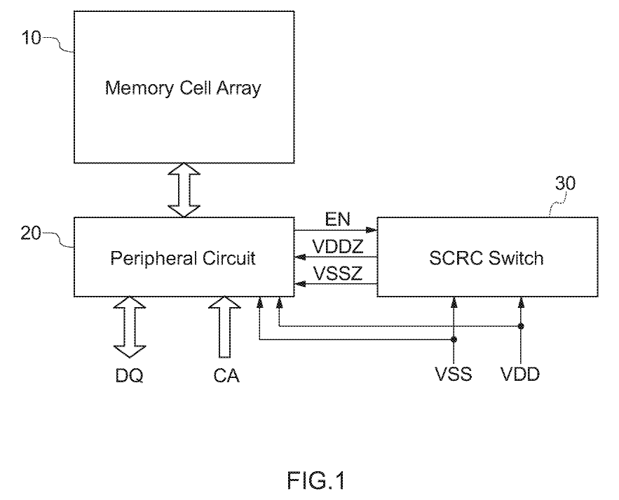

FIG. 1 is a block diagram showing a configuration of a semiconductor device according to an embodiment of the present disclosure. The semiconductor device shown in FIG. 1 is a DRAM, for example, and includes a memory cell array 10, a peripheral circuit 20, and an SCRC switch 30. The peripheral circuit 20 performs an access operation on the memory cell array 10 based on a command address signal CA supplied from outside. For example, when the command address signal CA indicates a read operation, read data DQ read from the memory cell array 10 is output outside. When the command address signal CA indicates a write operation, write data DQ input from outside is written in the memory cell array 10. The SCRC switch 30 supplies a pseudo power potential VDDZ and a pseudo ground potential VSSZ to the peripheral circuit 20. The pseudo power potential VDDZ is supplied from outside or generated based on a power potential VDD that is generated by an internal power circuit. The pseudo ground potential VSSZ is supplied from outside or generated based on a ground potential VSS that is generated by an internal power circuit. The level of the pseudo power potential VDDZ is substantially the same as that of the power potential VDD. The level of the pseudo ground potential VSSZ is substantially the same as that of the ground potential VSS. The SCRC switch 30 is controlled by an enable signal EN supplied from the peripheral circuit 20.

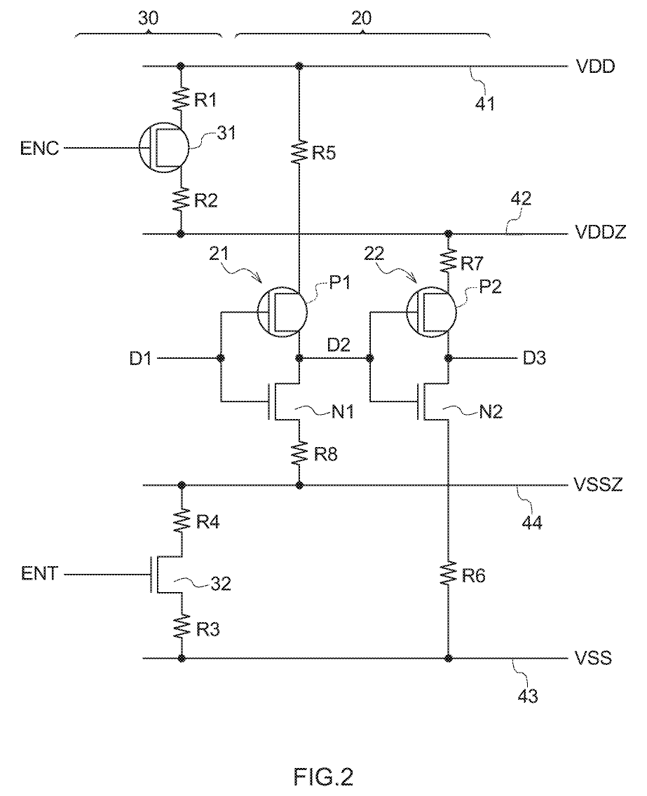

FIG. 2 is a circuit diagram for explaining a coupling relation between the peripheral circuit 20 and the SCRC switch 30. As shown in FIG. 2, the SCRC switch 30 includes a P-channel MOS transistor 31 and an N-channel MOS transistor 32. While one transistor 31 and one transistor 32 are shown in FIG. 2, in practice, a large number of transistors 31 connected to one another in parallel and a large number of transistors 32 connected to one another in parallel are included in the SCRC switch 30.

The transistor 31 is connected between a power line 41 supplied with the power potential VDD and a power line 42 supplied with the pseudo power potential VDDZ. The transistor 32 is connected between a power line 43 supplied with the ground potential VSS and a power line 44 supplied with the pseudo ground potential VSSZ. A gate electrode of the transistor 31 is supplied with a signal ENC obtained by inverting the enable signal EN. A gate electrode of the transistor 32 is supplied with a signal ENT being in phase with the enable signal EN. With this configuration, when the enable signal EN is activated to be at a high level, the transistors 31 and 32 are turned on. Accordingly, the power line 41 and the power line 42 are short-circuited via the transistor 31 and the power line 43 and the power line 44 are short-circuited via the transistor 32. Meanwhile, when the enable signal EN is at a low level, the transistors 31 and 32 are turned off. Accordingly, the power line 42 is isolated from the power line 41 and the power line 44 is isolated from the power line 43. Parasitic resistances R1 to R8 shown in FIG. 2 are added to the power lines 41 to 44.

A large number of functional circuits including gate circuits 21 and 22 are included in the peripheral circuit 20. The gate circuits 21 and 22 shown in FIG. 2 are both inverters. The gate circuit 21 is formed of a P-channel MOS transistor P1 and an N-channel MOS transistor N1 connected to each other in series between the power line 41 and the power line 44. Internal data D1 is commonly supplied to each gate electrode of the transistors P1 and N1. Internal data D2 is output from a common drain of the transistors P1 and N1. The gate circuit 22 is formed of a P-channel MOS transistor P2 and an N-channel MOS transistor N2 connected to each other in series between the power line 42 and the power line 43. The internal data D2 is commonly supplied to each gate electrode of the transistors P2 and N2. Internal data D3 is output from a common drain of the transistors P2 and N2.

When the enable signal EN is activated, the pseudo ground potential VSSZ having substantially the same potential as the ground potential VSS is supplied to a source of the transistor N1 and the pseudo power potential VDDZ having substantially the same potential as the power potential VDD is supplied to a source of the transistor P2. Accordingly, when the enable signal EN is activated, the gate circuits 21 and 22 operate normally. On the other hand, when the enable signal EN is deactivated, the pseudo ground potential VSSZ is not supplied to the source of the transistor N1 and the pseudo power potential VDDZ is not supplied to the source of the transistor P2. Therefore, when the enable signal EN is deactivated, the leakage current flowing into the gate circuits 21 and 22 is reduced. In a power down state where the enable signal EN is deactivated, the internal data D1 is fixed to be at a low level. With this configuration, the transistor P1 connected to the power line 41 is turned on, so that the level of the internal data D2 is maintained to be a high level, and the transistor N2 connected to the power line 43 is turned on, so that the level of the internal data D3 is maintained to be a low level. That is, even when the enable signal EN is deactivated, the logical state of the gate circuits 21 and 22 is maintained.

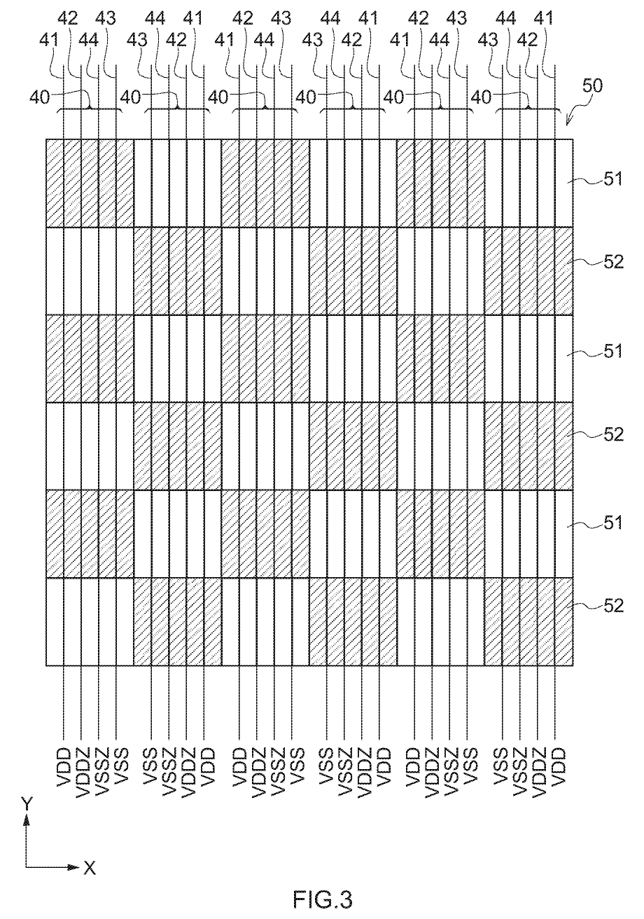

FIG. 3 is a schematic plan view showing a layout of the peripheral circuit 20 and the SCRC switch 30. In the example shown in FIG. 3, regions (unhatched regions) 51 in which the peripheral circuit 20 is arranged and regions (hatched regions) 52 in which the SCRC switch 30 is arranged constitute a checkerboarded pattern. That is, each region 51 is sandwiched in an X direction by regions 52 adjacent thereto on both sides in the X direction and is sandwiched in a Y direction by regions 52 adjacent thereto on both sides in the Y direction. Similarly, each region 52 is sandwiched in the X direction by regions 51 adjacent thereto on both sides in the X direction and is sandwiched in the Y direction by regions 51 adjacent thereto on both sides in the Y direction. The power lines 41 to 44 extending in the Y direction are arranged above the regions 51 and 52. That is, a power line set 40 formed of the power lines 41 to 44 is allocated to each cell column 50 formed of regions 51 and regions 52 that are alternately arrayed in the Y direction. In other words, only one power line set 40 is allocated to each of the regions 51 and 52 and a plurality of power line sets 40 are not allocated thereto. It is permissible that the widths of cell columns 50 in the X direction are constant. In this case, the width of the region 51 in the X direction and the width of the region 52 in the X direction match each other. It is permissible that the width of the region 51 in the Y direction and the width of the region 52 in the Y direction also match each other.

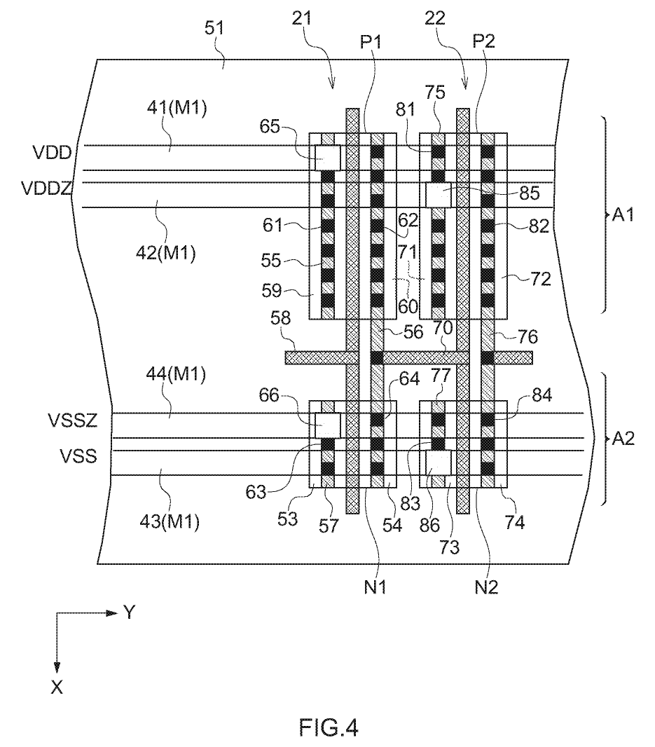

FIG. 4 is a schematic diagram showing an example of a layout of the gate circuits 21 and 22. The region 51 in which the gate circuits 21 and 22 are arranged includes a P-channel region A1 in which a P-channel MOS transistor is arranged and an N-channel region A2 in which an N-channel MOS transistor is arranged. Both the P-channel region A1 and the N-channel region A2 extend in the X direction and are adjacent to each other in the X direction. The transistors P1 and P2 shown in FIG. 2 are arranged in the P-channel region A1. The transistors N1 and N2 shown in FIG. 2 are arranged in the N-channel region A2.

The transistor P1 includes a gate electrode 58, a source region 59, and a drain region 60. The source region 59 is connected to a line 55 via a via conductor 61. The drain region 60 is connected to a line 56 via a via conductor 62. The line 55 is connected to the power line 41 located on an upper-layer wiring layer M1 via a via conductor 65. The portion of power line 41 located on the upper-layer wiring layer M1 may represent a section of a power line. The transistor N1 includes the gate electrode 58, a source region 53, and a drain region 54. The source region 53 is connected to a line 57 via a via conductor 63. The drain region 54 is connected to the line 56 via a via conductor 64. The line 57 is connected to the power line 44 located on the upper-layer wiring layer M1 via a via conductor 66. The portion of power line 44 located on the upper-layer wiring layer M1 may represent a section of a power line. With this configuration, when the internal data D1 is supplied to the gate electrode 58, the internal data D2 is output to the line 56.

The transistor P2 includes a gate electrode 70, a source region 71, and a drain region 72. The source region 71 is connected to a line 75 via a via conductor 81. The drain region 72 is connected to a line 76 via a via conductor 82. The line 75 is connected to the power line 42 located on the upper-layer wiring layer M1 via a via conductor 85. The portion of power line 42 located on the upper-layer wiring layer M1 may represent a section of a power line. The transistor N2 includes the gate electrode 70, a source region 73, and a drain region 74. The source region 73 is connected to a line 77 via a via conductor 83. The drain region 74 is connected to the line 76 via a via conductor 84. The line 77 is connected to the power line 43 located on the upper-layer wiring layer M1 via a via conductor 86. The portion of power line 43 located on the upper-layer wiring layer M1 may represent a section of a power line. With this configuration, when the internal data D2 is supplied to the gate electrode 70 connected to the line 56, the internal data D3 is output to the line 76.

In each region 51, a plurality of functional circuits including the gate circuits 21 and 22 are arrayed in the Y direction. The P-channel MOS transistor included in each of the gate circuits is supplied with the power potential VDD via the power line 41 or supplied with the pseudo power potential VDDZ via the power line 42. Further, the N-channel MOS transistor included in each of the gate circuits is supplied with the ground potential VSS via the power line 43 or supplied with the pseudo ground potential VSSZ via the power line 44.

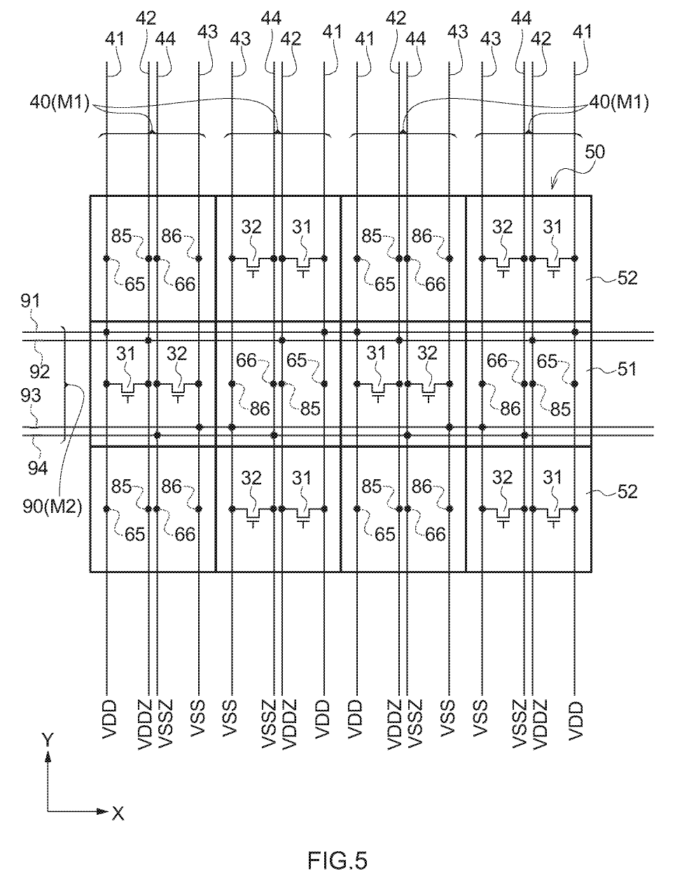

As shown in FIG. 5, the transistors 31 and 32 shown in FIG. 2 are arranged in each region 52. Therefore, drains of transistors 31 arranged in a plurality of regions 52 belonging to the same cell column 50 are commonly connected to one another via the power line 42 extending in the Y direction, and drains of transistors 32 arranged in a plurality of regions 52 belonging to the same cell column 50 are commonly connected to one another via the power line 44 extending in the Y direction. With this configuration, the pseudo power potential VDDZ is supplied to a plurality of gate circuits arranged in the regions 51 via the power lines 42 and the pseudo power potential VSSZ is supplied thereto via the power lines 44. Similarly, the power potential VDD is supplied to a plurality of gate circuits arranged in the regions 51 via power lines 41 and the power potential VSS is supplied thereto via power lines 43.

Since each region 51 is sandwiched in the Y direction by two regions 52 adjacent thereto in the Y direction, each length in the Y direction of power lines 41 to 44 coupling the transistors 31 and 32 included in the region 52 and gate circuits included in the region 51 is shortened. When each length of the power lines 42 and 44 is shortened, each resistance value of the parasitic resistances R2, R4, R7, and R8 shown in FIG. 2 is reduced. When each length of the power lines 41 and 43 is shortened, each resistance value of the parasitic resistances R5 and R6 shown in FIG. 2 is reduced. Further, power lines 41 and 43 allocated to cell columns 50 adjacent to each other in the X direction are arranged in such a manner that the power lines 41 are adjacent to each other and the power lines 43 are adjacent to each other. With this configuration, a region in which a P-channel MOS transistor is formed and a region in which an N-channel MOS transistor is formed are shared between cell columns 50 adjacent to each other in the X direction.

Further, in the example shown in FIG. 5, a power line set 90 including power lines 91 to 94 is arranged on a wiring layer M2 that is provided as an upper layer with respect to the power lines 41 to 44. The portion of a power line located on the wiring layer M2 may represent a section of a power line. Each of the power lines 91 to 94 extends in the X direction above the regions 51 and 52. The power line 91 short-circuits a plurality of power lines 41, the power line 92 short-circuits a plurality of power lines 42, the power line 93 short-circuits a plurality of power lines 43, and the power line 94 short-circuits a plurality of power lines 44. When the power lines 91 to 94 are arranged on the wiring layer M2, a meshed power line network is established with the power line sets 40 and 90, thereby enabling the power potential VDD, the pseudo power potential VDDZ, the ground potential VSS, and the pseudo power potential VSSZ to be more stable. Note that in the semiconductor device according to the present disclosure, since each length of the power lines 41 to 44 coupling the transistors 31 and 32 included in the region 52 and gate circuits included in the region 51 in the Y direction is short, providing the power lines 91 to 94 on the wiring layer M2 is not essential. Even when the power lines 91 to 94 are provided on the wiring layer M2, the number of required power lines 91 to 94 is small, so that a large number of lines other than the power lines 91 to 94 such as signal lines can be arranged on the wiring layer M2 on which the power lines 91 to 94 are to be provided.

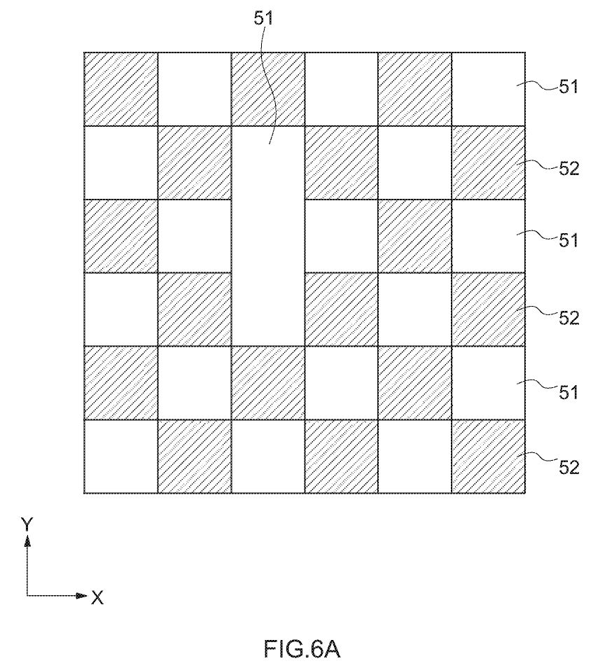

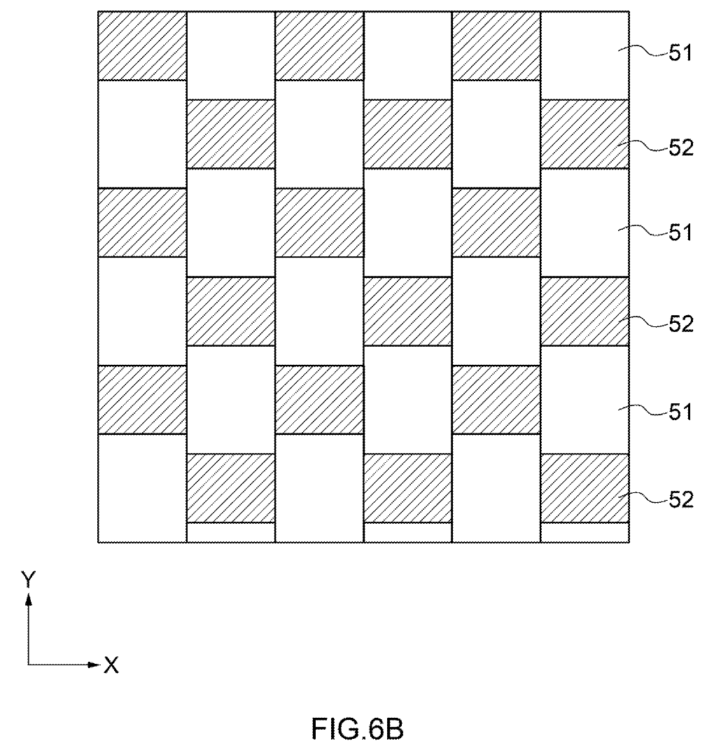

As described above, in the semiconductor device according to the present disclosure, regions 51 in which the peripheral circuit 20 is arranged and regions 52 in which the SCRC switch 30 is arranged constitute a checkerboarded pattern, so that the wiring length of each of the power lines 41 to 44 coupling gate circuits arranged in the regions 51 and SCRC switches 30 arranged in the regions 52 to one another can be shortened. Note that the regions 51 and the regions 52 do not need to constitute a complete checkerboarded pattern and as shown in FIG. 6A, it is permissible that a part of the regions 52 is replaced with a region 51, and as shown in FIG. 6B, it is permissible that the width of each region 51 in the Y direction is larger than the width of each region 52 in the Y direction. Even in FIGS. 6A and 6B, unhatched parts are regions 51 and hatched parts are regions 52.

Although this invention has been disclosed in the context of certain preferred embodiments and examples, it will be understood by those skilled in the art that the inventions extend beyond the specifically disclosed embodiments to other alternative embodiments and/or uses of the inventions and obvious modifications and equivalents thereof. In addition, other modifications which are within the scope of this invention will be readily apparent to those of skill in the art based on this disclosure. It is also contemplated that various combination or sub-combination of the specific features and aspects of the embodiments may be made and still fall within the scope of the inventions. It should be understood that various features and aspects of the disclosed embodiments can be combined with or substituted for one another in order to form varying mode of the disclosed invention. Thus, it is intended that the scope of at least some of the present invention herein disclosed should not be limited by the particular disclosed embodiments described above.

1. An apparatus comprising:
a plurality of first regions in which functional circuits are respectively disposed; and
a plurality of second regions in which first sub-threshold current reduction circuit (SCRC) switches each coupled between a first power line supplied with a first power potential and a second power line are respectively disposed,
wherein the functional circuit is configured to operate on the first power potential supplied at least from the second power line, and
wherein the plurality of first regions and the plurality of second regions are arranged in a substantially checkerboarded pattern.

2. The apparatus of claim 1, wherein the functional circuit includes a first gate circuit coupled between the second power line and a third power line supplied with a second power potential different from the first power potential.

3. The apparatus of claim 2,
wherein a second SCRC switch coupled between the third power line and a fourth power line is disposed in each of the plurality of second regions, and
wherein the functional circuit further includes a second gate circuit coupled between the first power line and the fourth power line.

4. The apparatus of claim 3,
wherein each of the first, second, third, and fourth power lines extends in a first direction, and
wherein a width of each of the plurality of first regions in a second direction perpendicular to the first direction is the same as a width of each of the plurality of second regions in the second direction.

5. The apparatus of claim 4, wherein a width of each of the plurality of first regions in the first direction is the same as a width of each of the plurality of second regions in the first direction.

6. An apparatus comprising:
a first region including a functional circuit; and
second, third, fourth, and fifth regions each including a first sub-threshold current reduction circuit (SCRC) switch coupled between a first power line supplied with a first power potential and a second power line,
wherein the first region is adjacent to the second region and the third region in a first direction such that the first region is arranged between the second region and the third region in the first direction,
wherein the first region is adjacent to the fourth region and the fifth region in a second direction perpendicular to the first direction such that the first region is arranged between the fourth region and the fifth region in the second direction,
wherein the functional circuit is configured to operate on the first power potential supplied at least from the second power line, and
wherein a width of each of the first, second, third, fourth, and fifth regions in the second direction is the same as one another.

7. The apparatus of claim 6, wherein a width of each of the first, second, third, fourth, and fifth regions in the first direction is the same as one another.

8. The apparatus of claim 6,
wherein the second power line includes a first section located on a first wiring layer and extending in the first direction above the first, second, and third regions, and
wherein the first section of the second power line is coupled to the functional circuit in the first region and to the first SCRC switch in each of the second region and the third region.

9. The apparatus of claim 8,
wherein the second power line further includes a second section located on a second wiring layer and extending in the second direction above the first, fourth, and fifth regions, and
wherein the second section of the second power line is coupled to the first section of the second power line and the first SCRC switch in each of the fourth region and the fifth region.

10. The apparatus of claim 9, wherein the functional circuit includes a first gate circuit coupled between the second power line and a third power line supplied with a second power potential different from the first power potential.

11. The apparatus of claim 10,
wherein a second SCRC switch coupled between the third power line and a fourth power line is disposed in each of the second, third, fourth, and fifth regions, and
wherein the functional circuit further includes a second gate circuit coupled between the first power line and the fourth power line.

12. The apparatus of claim 11,
wherein the fourth power line includes a third section located on the first wiring layer and extending in the first direction above the first, second, and third regions, and
wherein the third section of the fourth power line is coupled to the functional circuit in the first region and the first SCRC switch in each of the second region and the third region.

13. The apparatus of claim 12,
wherein the fourth power line further includes a fourth section located on the second wiring layer and extending in the second direction above the first, fourth, and fifth regions, and
wherein the fourth section of the fourth power line is coupled to the third section of the fourth power line and the first SCRC switch in each of the fourth region and the fifth region.

14. The apparatus of claim 13, wherein the functional circuit further includes a second gate circuit coupled between the first power line and the fourth power line.

15. An apparatus comprising:
a first region including a first sub-threshold current reduction circuit (SCRC) switch coupled between a first power line supplied with a first power potential and a second power line; and
second, third, fourth, and fifth regions each including a functional circuit,
wherein the first region is adjacent to the second region and the third region in a first direction such that the first region is arranged between the second region and the third region in the first direction,
wherein the first region is adjacent to the fourth region and the fifth region in a second direction perpendicular to the first direction such that the first region is arranged between the fourth region and the fifth region in the second direction,
wherein the functional circuit is configured to operate on the first power potential supplied from at least the second power line, and
wherein a width of each of the first, second, third, fourth, and fifth regions in the second direction is the same as one another.

16. The apparatus of claim 15,
wherein the second power line includes a first section located on a first wiring layer and extending in the first direction above the first, second, and third regions, and
wherein the first section of the second power line is coupled to the functional circuit in each of the second and third regions and the first SCRC switch in the first region.

17. The apparatus of claim 16,
wherein the second power line further includes a second section located on a second wiring layer and extending in the second direction above the first, fourth, and fifth regions, and
wherein the second section of the second power line is coupled to the first section of the second power line and the functional circuit in each of the fourth and fifth regions.

18. The apparatus of claim 17, wherein the functional circuit includes a first gate circuit coupled between the second power line and a third power line supplied with a second power potential different from the first power potential.

19. The apparatus of claim 18,
wherein a second SCRC switch coupled between the third power line and a fourth power line is disposed in the first region, and
wherein the functional circuit further includes a second gate circuit coupled between the first power line and the fourth power line.

20. The apparatus of claim 19,
wherein the fourth power line includes a third section located on the first wiring layer and extending in the first direction above the first, second, and third regions and a fourth section located on the second wiring layer and extending in the second direction above the first, fourth, and fifth regions,
wherein the third section of the fourth power line is coupled to the functional circuit in each of the second, third, fourth, and fifth regions and the first SCRC switch in the first region, and
wherein the fourth section of the fourth power line is coupled to the third section of the fourth power line and the functional circuit in each of the fourth and fifth regions.
